(19) United States
(12) Patent Application Publication
(10) Pub. No.: US 2024/0381539 A1
(43) Pub. Date: Nov. 14, 2024

(54) SINTERING PASTE, METHOD FOR ELECTRICALLY CONDUCTIVE, MATERIALLY BONDED CONNECTION OF AN ALUMINUM CONDUCTOR COVERED WITH AN OXIDE LAYER TO AN ELECTRONIC COMPONENT AND ELECTRONIC PRODUCT

(71) Applicant: MAHLE International GmbH, Stuttgart (DE)

(72) Inventor: Matthias Tuerpe, Ludwigsburg (DE)

(21) Appl. No.: 18/661,196

(22) Filed: May 10, 2024

(30) Foreign Application Priority Data
May 10, 2023 (DE) 102023204303.3

(51) Int. Cl. H05K 3/32; B23K 1/00; B23K 35/02; B23K 101/42; H05K 1/18

(52) U.S. Cl. CPC H05K 3/32; B23K 1/0016; B23K 35/025; H05K 1/181; B23K 2101/42; H05K 2203/1131

(57) ABSTRACT

A sintering paste may be utilized for the electrically conductive, materially bonded connection of an aluminum conductor covered with an oxide layer to an electronic component. The sintering paste may include nanoscale particles suitable for forming an electrically conductive, materially bonded connection of the aluminum conductor covered with the oxide layer to the electronic component via diffusion under the influence of pressure and temperature.

### CROSS-REFERENCE TO RELATED APPLICATION

This application claims priority to German Patent Application No. DE 102023204303.3, filed on May 10, 2023, the contents of which is hereby incorporated by reference in its entirety.

### TECHNICAL FIELD

The present invention relates to a sintering paste. The present invention relates in particular to a method for the electrically conductive, materially bonded connection of an aluminum conductor covered with an oxide layer to an electronic component and furthermore in particular to an electronic product with a corresponding connection.

### BACKGROUND

Due to various physical and technological advantages, copper is a dominant material for the production of electrical conductors in many technical areas. In electronics, soldering with (today predominantly lead-free) tin-based solders has established itself as the state of the art as a material bonding method for corresponding copper conductors with electronic components. Electrical conductors made of aluminum materials are an economically and technologically interesting alternative to copper conductors, as they are currently more cost-effective than copper conductors and also have a better conductivity-to-density ratio than copper conductors. However, in particular due to a high-melting Al₂O₃ oxide layer that spontaneously forms on the surface of an aluminum conductor in open air and that is only a few nanometers thick and firmly adhering, electrical aluminum conductors can only be joined to electronic components using complex and elaborate methods, see e.g. US 2019/0035764 A1 or DE 3115856 A1.

### SUMMARY

The task of the invention is therefore to provide an improved or at least a different embodiment of a materially bonding joining method for electrical aluminum conductors.

In the present invention, this task is solved in particular by the subject matter of the independent claim(s). Advantageous embodiments are the subject matter of the dependent claim(s) and the description.

The invention uses the knowledge that the Al₂O₃ oxide layer adhering to an aluminum conductor has imperfections such as lattice defects and the like, which allow diffusion processes under given boundary conditions. The basic idea of the invention is therefore that an electrically conductive, materially bonded connection between an aluminum conductor covered with an oxide layer on the one hand and an electronic component on the other hand can be realized by means of a sintering paste according to the invention and under the influence of pressure and relatively low temperature.

Accordingly, a sintering paste is proposed for the electrically conductive, materially bonded connection of an aluminum conductor covered with an oxide layer to an electronic component, wherein the sintering paste has nanoscale particles. These are suitable or designed to form an electrically conductive, thermally conductive, materially bonded connection between the aluminum conductor covered with an oxide layer and the electronic component by diffusion under the influence of pressure and temperature. On the one hand, the material of the aluminum conductor can be alloyed using the nanoscale particles and under the influence of pressure and temperature, wherein the invention makes use of the aforementioned finding that the nanoscale particles diffuse through lattice defects and the like in an Al₂O₃ oxide layer covering the aluminum conductor. On the other hand, the nanoscale particles alloy a material of a contact element of the electronic component. As a result, despite the Al₂O₃ oxide layer on the aluminum conductor, the proposed sintering paste can be used to provide an electrically conductive, materially bonded connection between the aluminum conductor and the electronic component. The nanoscale particles have dimensions in the nanometer range.

A range of approx. 1 to 100 nm is usually referred to as nanoscale.

The material for the aluminum conductor can be pure aluminum or an aluminum alloy, in particular an alloy of aluminum and, for example, small amounts of copper and/or silicon.

The term “aluminum conductor” should be interpreted broadly in the present case. In particular, it can refer to any electrically conductive body made of an aluminum material as defined above. An aluminum conductor can be, for example, an aluminum conductor track, an electrical busbar box or any aluminum conductor component. In addition to the actual conductor track, a corresponding aluminum conductor track can have integral connecting elements made of an aluminum material, e.g. an aluminum contact pin or aluminum contact wire and/or at least one connecting surface made of aluminum material, e.g. an aluminum material coating. The actual conductor track can be made of the aluminum material or another material.

The said aluminum conductor can be arranged on a support structure. Conveniently, the support structure is designed as a PCB (printed circuit board) or IMS board (insulated metal substrate), wherein the aluminum conductor arranged on the PCB or IMS board is implemented as an aluminum conductor track.

Furthermore, the term “electronic component” should be interpreted broadly, i.e. an electronic component can be any electronic component.

It is expedient to provide that the nanoscale particles are nanoscale non-ferrous metal particles. Non-ferrous metals within the meaning of the invention are non-ferrous metals, wherein light metals and/or the precious metals gold and platinum are expediently excluded.

In particular, it may be provided that the nanoscale particles are formed from one or more of the following non-ferrous metals or comprise one or more of the following non-ferrous metals at least in part: copper, silver or silicon. Using the specified non-ferrous metals, the materially bonded connection of the aluminum conductor covered with an oxide layer to the electronic component according to the invention can be achieved at comparatively low pressure and comparatively low temperature. The applicant has found in tests that the said non-ferrous metals migrate (diffuse) particularly well and especially at relatively low temperatures through lattice defects and the like in an Al₂O₃ oxide layer covering the aluminum conductor, which supports the formation of materially bonded connections of an aluminum conductor covered with an oxide layer with an electronic component.

It may be useful for the sintering paste not to contain iron. This means that the sintering paste is free of iron. This also helps to promote the formation of materially bonded connections between an aluminum conductor covered with an oxide layer and an electronic component.

In accordance with a further basic idea of the invention, a method for electrically conductive, materially bonded connection of an aluminum conductor covered with an oxide layer to an electronic component is proposed. The method according to the invention provides that an electrically conductive, aluminum conductor covered with an oxide layer and an electronic component are first provided. A sintering paste as described above is then applied, in particular exclusively, to a surface of the aluminum conductor covered with an oxide layer. Then said electronic component is positioned on the aluminum conductor covered with an oxide layer provided with sintering paste in such a way that a contact surface of the electronic component and the surface of the aluminum conductor covered with an oxide layer are wetted with sintering paste. Finally, the composite formed from the electronic component, the sintering paste and the aluminum conductor covered with an oxide layer is sintered at a specified joining pressure and temperature using a sintering press. This demonstrates an advantageous method in which an electrically conductive, materially bonded connection between an aluminum conductor covered with an oxide layer and any electronic component with a contact surface can be realized using a sintering paste according to the invention and a commercially available sintering press, for example. The set joining pressure and the set joining temperature are relatively low, in particular so low that electronic components are not negatively affected or damaged during the formation of the materially bonded connection. The proposed method can also be used as a substitute for the usual bonding of aluminum conductors and to increase the service life and reliability of such bond connections. Using the proposed method, aluminum can be used as a less expensive conductor material, providing cost-cutting potential for numerous electronic products. The proposed method also eliminates the need for aggressive fluxes and the like.

Conveniently, the method may provide for the sintering paste to be applied to the surface of the aluminum conductor covered with an oxide layer by means of a printing method, in particular a screen printing method. This allows a layer of sintering paste with a uniform thickness to be applied to said surface using simple and cost-effective means. It should be understood that the present inventive method is not limited to the use of a printing method, but that in principle equally effective application methods can also be used.

Further expediently, the method may provide that the predetermined joining pressure during sintering of said composite is 5 MPa to 50 MPa, in particular 10 MPa to 20 MPa, and/or the predetermined joining temperature during sintering of said composite is 100° C. to 400° C., in particular 150° C. to 250° C. It has been recognized that at an appropriate joining pressure and temperature, the nanoscale particles contained in the sintering paste used can migrate (diffuse) particularly well through the lattice defects and the like of an Al₂O₃ oxide layer covering the aluminum conductor and alloy with the material of the aluminum conductor. It is preferable if the joining pressure set in the method during sintering of said composite is/are in the range from 10 MPa to 20 MPa and/or the joining temperature during sintering of said composite is/are in the range from 150° C. to 250° C. With these method parameters (joining pressure and/or joining temperature), pressure-sensitive and/or temperature-sensitive electronic components can also be materially bonded to aluminum conductors covered with an oxide layer.

Conveniently, the method may also provide for the sintering paste to be applied to the contact surface of the electronic component. This can also be conveniently carried out using a printing method, in particular screen printing method. As a result, sintering paste is applied to both sides, namely to the surface of the aluminum conductor covered with an oxide layer and to the contact surface of the electronic component. In principle, the sintering paste can be applied to the contact surface of the electronic component after, before or at the same time as the sintering paste is applied to the surface of the aluminum conductor covered with an oxide layer. By wetting both sides, it can be ensured that the surface of the aluminum conductor covered with an oxide layer and the contact surface of the electronic component are completely, i.e. without gaps, covered by sintering paste.

Another useful aspect of the method is that the surface of the aluminum conductor covered with an oxide layer is pretreated with a non-ferrous pretreatment agent before the sintering paste is applied to the surface of the aluminum conductor covered with an oxide layer. The non-ferrous pre-treatment agent is preferably made up of metal pre-treatment particles. These can preferably be made of one or more of the following non-ferrous metals or contain at least a proportion of them: copper, silver or silicon. The metal pretreatment particles of the pretreatment agent adhere to lattice defects or the like present in the Al₂O₃ oxide layer of the aluminum conductor, which supports the diffusion processes during the subsequent sintering of said composite. This has the advantage that the formation of the electrically conductive, materially bonded connection between the aluminum conductor covered with an oxide layer and the electronic component is faster and with improved process reliability. The pre-treatment agent can, for example, be an aqueous solution, in particular water, a salt solution or a diluted acid.

According to a further basic idea of the invention, an electronic product is provided which has at least one electrically conductive, materially bonded connection between an aluminum conductor covered with an oxide layer of the product and an electronic component of the product, wherein the at least one connection is produced with a sintering paste according to the preceding description and/or by a method according to the preceding description. This provides an advantageous electronic product with at least one advantageous electrically conductive, materially bonded connection. Appropriately designed connections can improve heat conduction in electronic products. In addition, the operating temperature of corresponding electronic products can be increased, as this is no longer limited by solder connections (melting temperature of tin 232° C.), as is the case with classic PCBs, but only by the organic PCB material.

To summarize, it remains to be said: The present invention preferably relates to a sintering paste for the electrically conductive, materially bonded connection of an aluminum conductor covered with an oxide layer to an electronic component, wherein the sintering paste comprises nanoscale particles which are suitable for forming an electrically conductive, materially bonded connection of the aluminum conductor covered with an oxide layer to the electronic component by diffusion under the influence of pressure and temperature. The invention relates in particular to a method for the electrically conductive, materially bonded connection of an aluminum conductor covered with an oxide layer to an electronic component and also in particular to an electronic product having at least one electrically conductive, materially bonded connection.

Other important features and advantages of the invention can be seen from the dependent claims, from the drawings and from the associated description of the figure based on the drawings.

It is understood that the above-mentioned features and those yet to be explained below can be used not only in the combination indicated in each case, but also in other combinations or on their own, without deviating from the scope of the present invention.

Preferred embodiments of the invention are shown in the drawings and are explained in more detail in the following description, wherein identical reference signs refer to identical or similar or functionally identical components.

### BRIEF DESCRIPTION OF THE DRAWINGS

They show, schematically in each case

FIG. 1 shows a cross-section of an aluminum conductor covered with an oxide layer, which is arranged on a support structure designed as a PCB board,

FIGS. 2 and 3 show the cross-section from FIG. 1, illustrating a method for electrically conductive, materially bonded connection of the aluminum conductor covered with an oxide layer to an electronic component, which is only indicated in FIG. 3.

### DETAILED DESCRIPTION

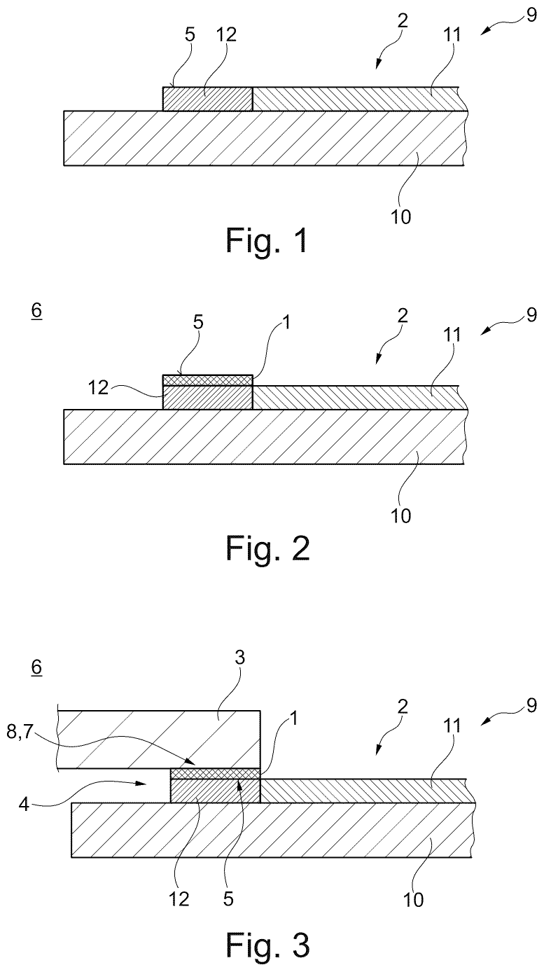

FIG. 1 shows a preferred embodiment of an aluminum conductor 2, which is arranged on a support structure 10 designed as a PCB board. In this example, the aluminum conductor 2 has an aluminum conductor track 11 made of an electrically conductive aluminum material and a connecting element 12 made of the same aluminum material that is integrally attached to it. The aluminum conductor 2 is covered by an Al₂O₃ oxide layer only a few nanometers thick, which has formed spontaneously on a surface of the aluminum conductor 2 in air and adheres firmly to the aluminum conductor 2. The PCB board is made from organic circuit board material in the usual way. The aluminum conductor 2 and the support structure 10 form an example of any electronic product 9.

FIGS. 2 and 3 show a method, labeled 6 in total, for electrically conductive, materially bonded connection of the aluminum conductor covered with an oxide layer 2 to an electronic component 3, which is only indicated in FIG. 3.

In FIG. 2 it can be seen that, after the electrically conductive, aluminum conductor covered with an oxide layer 2 and the electronic component 3 have been provided, a relatively thin layer of sintering paste 1, symbolized by a cross-hatched box, is applied exclusively to a surface 5 of the aluminum conductor covered with an oxide layer 2, which in the present case is formed by the connecting element 12. The electronic component 3 is then positioned on the aluminum conductor covered with an oxide layer 2 prepared with sintering paste 1 in the manner illustrated in FIG. 3. As a result, a contact surface 7 of a contact element 8 of the electronic component 3 facing the aluminum conductor 2 and the surface 5 of the aluminum conductor covered with an oxide layer 2 are completely and, in particular, completely wetted with sintering paste 1. Subsequently, in a step not illustrated here, the composite formed from the electronic component 3, the sintering paste 1 and the aluminum conductor covered with an oxide layer 2 is sintered at a predetermined joining pressure in the range from 5 MPa to 50 MPa, in particular 10 MPa to 20 MPa, and a predetermined joining temperature in the range from 100° C. to 400° C., in particular 150° C. to 250° C., by means of a sintering press.

The sintering paste 1 has nanoscale particles which are suitable for forming an electrically conductive, materially bonded connection 4 of the aluminum conductor covered with an oxide layer 2 to the electronic component 3 by diffusion under the influence of said joining pressure and said joining temperature in the course of said method 6. The invention makes use of the knowledge that the Al₂O₃ oxide layer adhering to the aluminum conductor covered with an oxide layer 2 has imperfections such as lattice defects and the like, which allow diffusion processes under the set boundary conditions during sintering. As a result, despite the Al₂O₃ oxide layer present on the aluminum conductor covered with an oxide layer 2, an electrically conductive, materially bonded connection 4 can be produced between the aluminum conductor covered with an oxide layer 2 and the electronic component 3 using the proposed sintering paste 1 at a relatively low joining pressure and at a relatively low joining temperature.

1. A sintering paste for the electrically conductive, materially bonded connection of an aluminum conductor covered with an oxide layer to an electronic component, the sintering paste comprising nanoscale particles suitable for forming an electrically conductive, materially bonded connection of the aluminum conductor covered with the oxide layer to the electronic component via diffusion under the influence of pressure and temperature.

2. The sintering paste according to claim 1, wherein the nanoscale particles are nanoscale non-ferrous metal particles.

3. The sintering paste according to claim 1, wherein the nanoscale particles contain at least one of copper, silver, and silicon.

4. The sintering paste according to claim 1, wherein the sintering paste is free of iron.

5. A method for producing an electrically conductive, materially bonded connection of an aluminum conductor covered with an oxide layer to an electronic component in its frame, the method comprising:
providing the electrically conductive aluminum conductor covered with the oxide layer and providing the electronic component;
applying a sintering paste according to claim 1 to a surface of the aluminum conductor covered with the oxide layer;
positioning the electronic component on the aluminum conductor covered with the oxide layer provided with the sintering paste such that a contact surface of the electronic component and the surface of the aluminum conductor covered with the oxide layer are wetted with the sintering paste; and
sintering a composite formed from the electronic component, the sintering paste, and the aluminum conductor covered with the oxide layer at a predetermined joining pressure and a predetermined joining temperature using a sintering press.

6. The method according to claim 5, wherein the sintering paste is applied to the surface of the aluminum conductor covered with the oxide layer via a printing process.

7. The method according to claim 5, wherein:
the predetermined joining pressure is 5 MPa to 50 MPa; and
the predetermined joining temperature is 100° C. to 400° C.

8. The method according to claim 5, further comprising applying the sintering paste to the contact surface of the electronic component.

9. The method according to claim 5, further comprising, before applying the sintering paste to the surface of the aluminum conductor covered with the oxide layer, pretreating the surface of the aluminum conductor covered with the oxide layer with a non-ferrous pretreatment agent.

10. An electronic product, comprising:
an aluminum conductor covered including an oxide layer; and
an electronic component;
wherein at least one electrically conductive, materially bonded connection between the aluminum conductor and the electronic component is provided via a sintering paste according to claim 1.

11. The electronic product according to claim 10, further comprising a support structure on which the aluminum conductor is arranged.

12. The electronic product according to claim 11, wherein the support structure is at least one of a printed circuit board and an insulated metal substrate.

13. The electronic product according to claim 12, wherein the aluminum conductor is an aluminum conductor track.

14. The electronic product according to claim 10, wherein the oxide layer is an Al₂O₃ oxide layer.

15. The method according to claim 5, wherein the sintering paste is applied exclusively to the surface of the aluminum conductor covered with the oxide layer.

16. The method according to claim 5, wherein applying the sintering paste to the surface of the aluminum conductor includes forming a layer of the sintering paste with a uniform thickness.

17. The method according to claim 5, wherein:
the oxide layer is an Al₂O₃ oxide layer disposed on the surface of the aluminum conductor; and
the sintering paste is applied to the oxide layer disposed on the surface of the aluminum conductor.

18. The method according to claim 5, wherein sintering the composite includes diffusing the nanoscale particles of the sintering paste through a plurality of lattice defects present in the oxide layer.

19. The method according to claim 7, wherein:
the predetermined joining pressure is 10 MPa to 20 MPa; and
the predetermined joining temperature is 150° C. to 250° C.

20. The method according to claim 9, wherein pretreating the surface of the aluminum conductor covered with the oxide layer includes adhering metal pretreatment particles of the non-ferrous pretreatment agent to defects present in the oxide layer.
